(19) United States
(12) Patent Application Publication
(10) Pub. No.: US 2026/0283001 A1
(43) Pub. Date: Sep. 17, 2026

(54) SEMICONDUCTOR STRUCTURE

(71) Applicant: Taiwan Semiconductor Manufacturing Company, Ltd., Hsinchu (TW)

(72) Inventors: Chao-Wei Chiu, Hsinchu City (TW); Ying-Jui Huang, Hsinchu County (TW); Kung-Chen Yeh, Taichung City (TW); Wei-Yu Chen, New Taipei City (TW); Cheng-Shiuan Wong, Hsinchu City (TW); Hao-Jan Pei, Hsinchu (TW); Hsiu-Jen Lin, Hsinchu County (TW)

(73) Assignee: Taiwan Semiconductor Manufacturing Company, Ltd., Hsinchu (TW)

(21) Appl. No.: 19/082,139

(22) Filed: Mar. 17, 2025

(51) Int. Cl. H01L 23/31; H01L 23/00; H01L 23/13; H01L 23/14; H01L 23/498; H01L 23/538; H01L 25/065

(52) U.S. Cl. CPC H10W 74/114; H10W 70/611; H10W 70/65; H10W 70/68; H10W 70/69; H10W 90/401; H10W 72/0198; H10W 74/10; H10W 80/312; H10W 80/327; H10W 90/00; H10W 90/701; H10W 90/794

(57) ABSTRACT

A semiconductor structure includes a first semiconductor substrate, a second semiconductor substrate disposed on the first semiconductor substrate, and a dielectric layer disposed between the first semiconductor substrate and the second semiconductor substrate. In a cross-sectional view, a sidewall surface of the dielectric layer is aligned with a sidewall surface of the second semiconductor substrate, and a sidewall surface of the first semiconductor substrate protrudes outward from the sidewall surface of the dielectric layer.

### BACKGROUND

Singulation processes are usually achieved by blade sawing or laser grooving. Blade sawing has short processing times, but have difficulty removing certain materials, such as dielectric materials with a dielectric constant less than 3. Laser grooving is widely used to remove the dielectric materials, but laser grooving may cause recast or delamination.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a singulation step according to some embodiments of the present disclosure.

FIG. 2 is a cross-sectional view of a semiconductor structure according to some embodiments of the present disclosure.

FIG. 3 is an enlarged view of region R1 in FIG. 2.

FIG. 4 is a cross-sectional view of a singulation step according to some embodiments of the present disclosure.

FIG. 5 is a cross-sectional view of a semiconductor structure according to some embodiments of the present disclosure.

FIG. 6 is an enlarged view of region R2 in FIG. 5.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A substrate (e.g., a wafer) on which integrated circuits are formed can be separated into a plurality of semiconductor structures (or a plurality of semiconductor die) through a singulation process. The singulation process can be accomplished by cutting the substrate (and layers thereon) along the scribe lines by blade sawing or laser grooving. Although laser grooving can cut (or remove) a layer (e.g., a dielectric layer having a dielectric constant less than 3) that is difficult to cut (or remove) by saw blades, laser grooving can easily cause delamination between heterogeneous materials. In addition, when the dielectric layer is located below a semiconductor substrate (e.g., a silicon substrate), that is, the semiconductor substrate and the dielectric layer are cut by laser grooving in sequence, recast may occur on sidewall surfaces of the semiconductor substrate after cutting the dielectric layer, which reduces the strength of the singulated semiconductor structure (or the singulated semiconductor die).

In the present disclosure, the structure in which a dielectric layer (e.g., a dielectric layer having a dielectric constant less than 3) is sandwiched between two semiconductor substrates is singulated by at least two blade sawing processes, wherein the first blade sawing process is used to cut the dielectric layer and the semiconductor substrate (also referred to as “second semiconductor substrate”) disposed on the dielectric layer, and the second blade sawing process is used to cut the semiconductor substrate (also referred to as “first semiconductor substrate) disposed under the dielectric layer. During the first blade sawing process, the semiconductor substrate disposed on the dielectric layer provides a hard force-applying surface, which is beneficial for the saw blade to cut through the dielectric layer. In addition, during the first blade sawing process, the semiconductor substrate disposed on the dielectric layer can resist the peeling force generated by blade sawing, which helps to reduce the peeling of the dielectric layer. Using blade sawing rather than laser grooving to cut the dielectric layer disposed under the semiconductor substrate can improve the aforementioned recast and delamination issues generated by laser grooving and/or shorten the processing time.

A cutting width of the second blade sawing process can be narrower than a cutting width of the first blade sawing process to provide a buffer for variations (e.g., variations in saw blade width, and/or variations in saw blade shift during the singulation process.) As a result, in the semiconductor structure (or the singulated semiconductor die) formed by the singulation process, a sidewall surface of the dielectric layer is aligned with a sidewall surface of the semiconductor substrate disposed on the dielectric layer, and a sidewall surface of the semiconductor substrate disposed below the dielectric layer protrudes outward from the sidewall surface of the dielectric layer. In addition, since blade sawing processes can provide a vertical or nearly vertical sidewall surface for the cut object, a maximum lateral distance between two opposite ends of each of the sidewall surfaces (generated by the two blade sawing processes) of the semiconductor substrates and dielectric layer can be less than 5 μm. Moreover, since the blade saw in the first blade sawing process stops inside the structure on which the first blade sawing process is performed, an arc-shaped structure generated by the first blade sawing process may be formed inside the resulting semiconductor structure.

Optionally, layers or structures disposed on the upper semiconductor substrate (the semiconductor substrate disposed on the dielectric layer) are cut by a laser grooving process. Since laser beams have divergence angles (the beam diameter increases as the distance to the focal point increases), the sidewall surface (e.g., a third sidewall surface) produced by the laser grooving process is inclined rather than vertical, so the sidewall surfaces (e.g., a first sidewall surface and a second sidewall surface) produced by the two blade sawing processes are steeper than the sidewall surface produced by the laser grooving process. Optionally, the lower semiconductor substrate (the semiconductor substrate disposed under the dielectric layer) may be removed from the singulated semiconductor structure such that the resulting semiconductor structure does not include the lower semiconductor substrate.

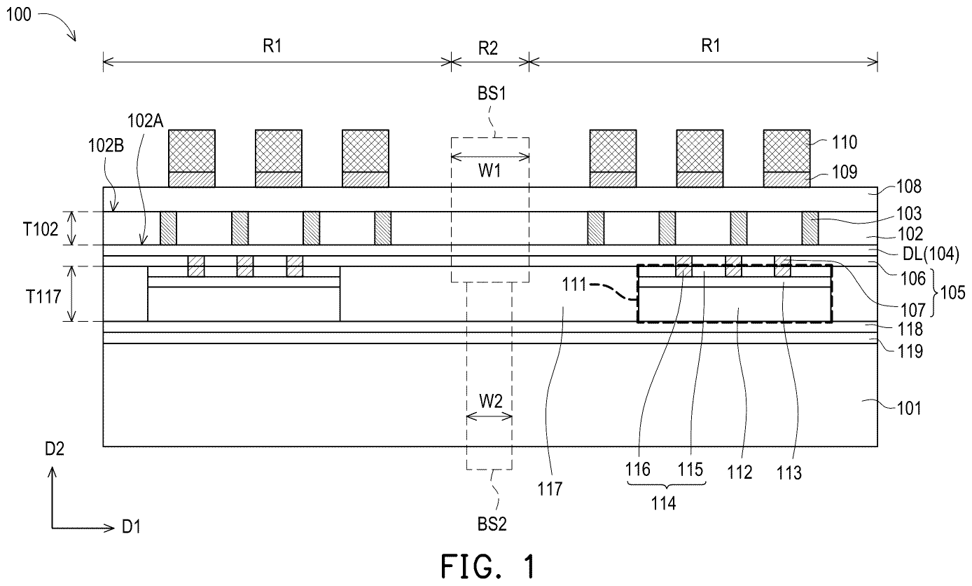

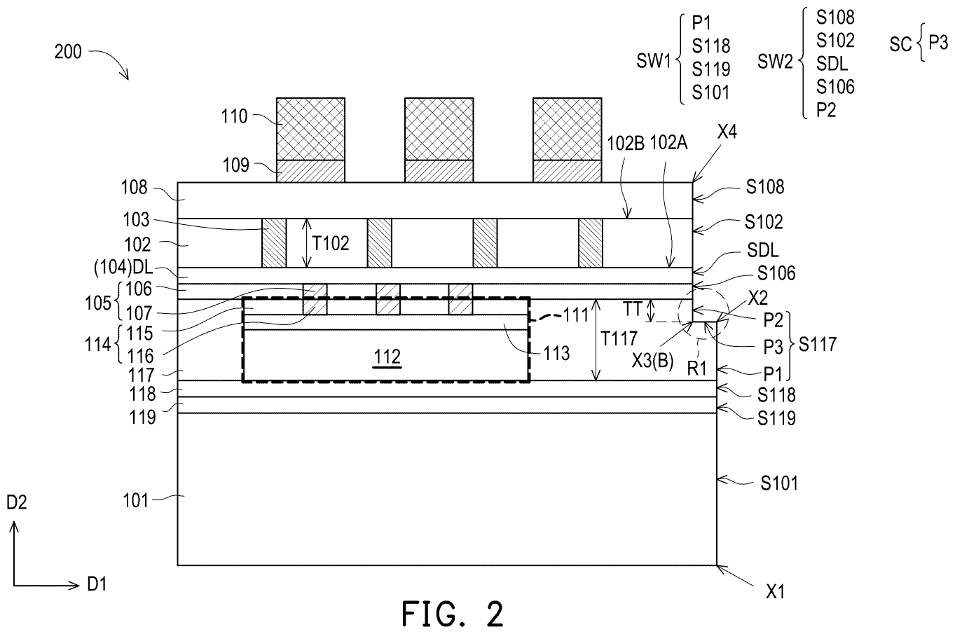

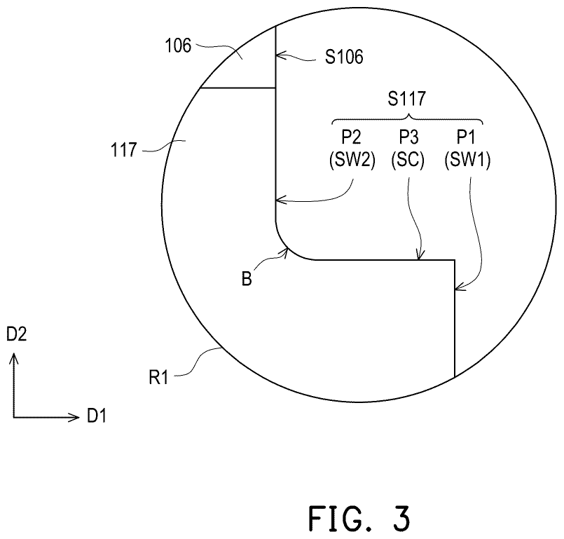

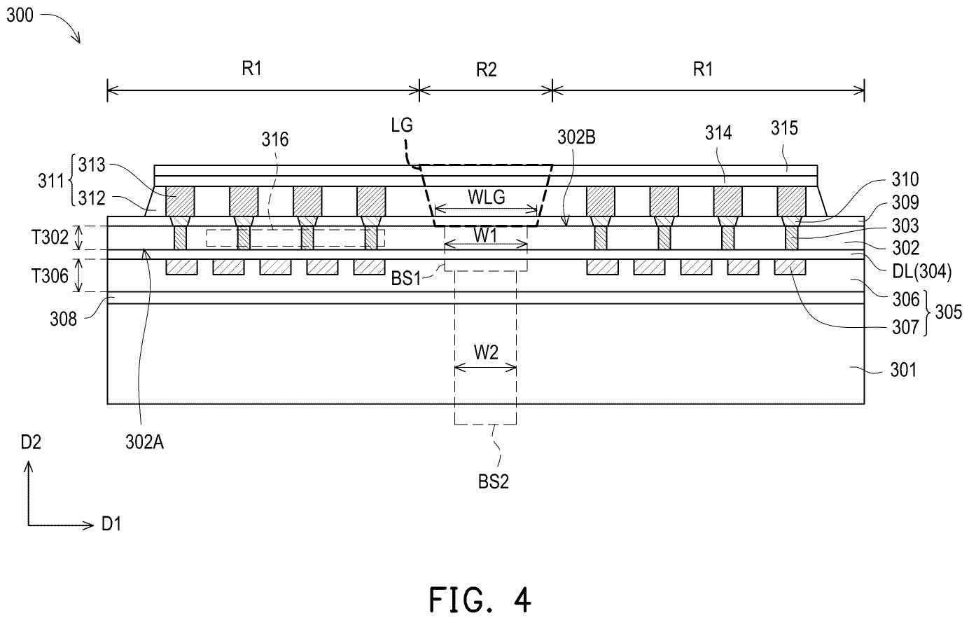

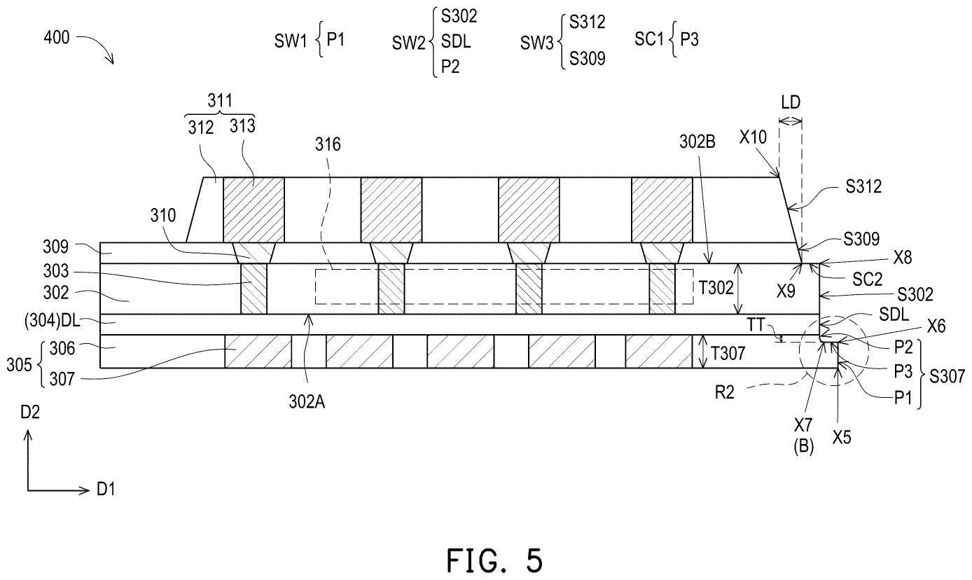

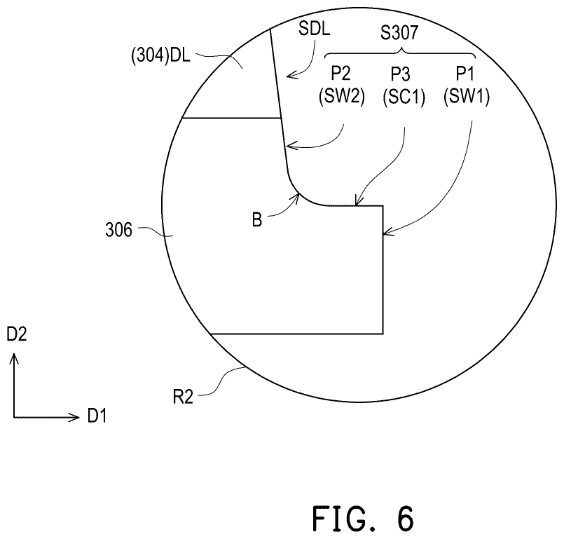

FIG. 1 is a cross-sectional view of a singulation step according to some embodiments of the present disclosure. FIG. 2 is a cross-sectional view of a semiconductor structure according to some embodiments of the present disclosure. FIG. 3 is an enlarged view of region R1 in FIG. 2. FIG. 4 is a cross-sectional view of a singulation step according to some embodiments of the present disclosure. FIG. 5 is a cross-sectional view of a semiconductor structure according to some embodiments of the present disclosure. FIG. 6 is an enlarged view of region R2 in FIG. 5. It should be noted that the drawings only illustrate specific examples for convenience of explanation, but are not intended to limit the present disclosure. For example, design parameters such as the number of components and relative arrangement relationships can be changed according to needs and are not limited to those shown in the drawings.

Referring to FIG. 1, a structure 100 to be separated into a plurality of semiconductor structures (e.g., a semiconductor structure 200 shown in FIG. 2) through a singulation process is provided. The structure 100 includes, for example, a semiconductor substrate 101, a semiconductor substrate 102, a plurality of conductive vias 103, an interconnect structure 104, a bonding structure 105, a redistribution structure 108, a plurality of die connectors 109, a plurality of conductive connectors 110, a plurality of integrated circuit dies 111, a gap filling layer 117, a bonding film 118 and a bonding film 119, but not limited thereto. One or more layers or components may be included in the structure 100 according to different needs.

The semiconductor substrate 101 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the semiconductor substrate 101 is made of semiconductor materials, such as semiconductor materials of the groups III-V of the periodic table. In some embodiments, the semiconductor substrate 101 includes elementary semiconductor materials such as silicon or germanium; compound semiconductor materials such as silicon carbide, gallium arsenide, indium arsenide, or indium phosphide; alloy semiconductor materials such as SiGe, GaAsP, AlInAs, AlGaAs, GaInAs, GaInP, or GaInAsP; or combinations thereof. Other substrates, such as multi-layered or gradient substrates, may also be used. In some embodiments, although not shown, the semiconductor substrate further includes active or passive devices, such as transistors, capacitors, resistors, or diodes formed therein.

The semiconductor substrate 102 is disposed on the semiconductor substrate 101. The semiconductor substrate 102 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the semiconductor substrate 102 is made of semiconductor materials, such as semiconductor materials of the groups III-V of the periodic table. In some embodiments, the semiconductor substrate 102 includes elementary semiconductor materials such as silicon or germanium; compound semiconductor materials such as silicon carbide, gallium arsenide, indium arsenide, or indium phosphide; alloy semiconductor materials such as SiGe, GaAsP, AlInAs, AlGaAs, GaInAs, GaInP, or GaInAsP; or combinations thereof. Other substrates, such as multi-layered or gradient substrates, may also be used. In some embodiments, although not shown, the semiconductor substrate further includes active or passive devices, such as transistors, capacitors, resistors, or diodes formed therein. The composition and/or material of the semiconductor substrate 101 and the semiconductor substrate 102 may be different or the same.

The plurality of conductive vias 103 extend through the semiconductor substrate 102 and can be referred to as through-silicon vias or through-substrate vias (TSVs). As an example, the plurality of conductive vias 103 may be formed by forming recesses in the semiconductor substrate 102 by, for example, etching, milling, laser techniques, a combination thereof, or the like. A thin dielectric material may be formed in the recesses, such as by using an oxidation technique. A barrier layer may be conformally deposited in the openings, such as by chemical vapor deposition (CVD), atomic layer deposition (ALD), physical vapor deposition (PVD), thermal oxidation, a combination thereof, or the like. The barrier layer may be formed from an oxide, a nitride, or an oxynitride, such as titanium nitride, titanium oxynitride, tantalum nitride, tantalum oxynitride, tungsten nitride, a combination thereof, and/or the like. A conductive material may be deposited over the barrier layer and in the openings. The conductive material may be formed by an electro-chemical plating process, CVD, PVD, a combination thereof, or the like. Examples of conductive materials are copper, tungsten, aluminum, silver, gold, a combination thereof, or the like. Excess of the conductive material and the barrier layer is removed from the surface (e.g., a first surface 102A) of the semiconductor substrate 102 by, for example, a chemical-mechanical planarization (CMP) process or the like. The semiconductor substrate 102 may then be thinned in subsequent processing by performing a thinning process on a second surface 102B of the semiconductor substrate 102 using a CMP process, a grinding process, an etch-back process, a combination thereof, or the like so that the plurality of conductive vias 103 are exposed by the second surface 102B of the semiconductor substrate 102.

The interconnect structure 104 is disposed on the first surface 102A of the semiconductor substrate 102. The interconnect structure 104 may interconnect elements on the same side or opposite sides of the semiconductor substrate 102. The interconnect structure 104 may include one or more stacked dielectric layers (only one dielectric layer DL is shown) and one or more layers of conductive features (not shown) formed in the one or more stacked dielectric layers. Each of the stacked dielectric layers may include a dielectric material having a dielectric constant less than 3, such as a low-k (low dielectric constant) material, an extreme low dielectric constant (ELK) material, or the like. For example, the dielectric material includes an oxide, SiO₂, borophosphosilicate glass (BPSG), tetraethyl orthosilicate (TEOS), spin on glass (SOG), undoped silicate glass (USG), fluorinated silicate glass (FSG), high-density plasma (HDP) oxide, or plasma-enhanced TEOS (PETEOS), or the like. The dielectric layers may be deposited using an appropriate process, such as CVD, ALD, PVD, plasma-enhanced chemical vapor deposition (PECVD), or the like.

The conductive features may include conductive lines and conductive vias interconnecting the layers of conductive lines. The conductive vias may extend through respective ones of the dielectric layers to provide vertical connections between layers of the conductive lines. The conductive features may be formed through any acceptable process, such as a damascene process, a dual damascene process, or the like.

In some embodiments, the conductive features may be formed using a damascene process in which a respective dielectric layer is patterned utilizing a combination of photolithography and etching techniques to form trenches corresponding to the desired pattern of the conductive features. An optional diffusion barrier and/or optional adhesion layer may be deposited and the trenches may then be filled with a conductive material. Suitable materials for the barrier layer include titanium, titanium nitride, titanium oxide, tantalum, tantalum nitride, titanium oxide, combinations thereof, or the like, and suitable materials for the conductive material include copper, silver, gold, tungsten, aluminum, ruthenium, cobalt, molybdenum, combinations thereof, or the like. In some embodiments, the conductive features may be deposited by front-end-of-line (FEOL) processes, which allows for high-temperature materials to be used for the conductive material. In some embodiments, the conductive features may be formed by depositing a seed layer of copper or a copper alloy, and filling the trenches by electroplating. A CMP process or the like may be used to remove excess conductive material from a surface of the respective dielectric layer and to planarize surfaces of the dielectric layer and the conductive features for subsequent processing.

Although the interconnect structure 104 is illustrated in FIG. 1 as extending across a surface of the semiconductor substrate 102, in some embodiments, individual interconnect structures 104 may be formed in each of device regions R1 and the individual interconnect structures 104 may be separated from one another by a scribe line region R2. The interconnect structure 104 may be separated using a suitable etching process, such as an isotropic etching process (e.g., a wet etching process), an anisotropic etching process (e.g., a dry etching process), multiple processes or combinations thereof, or the like.

Alternatively, dielectric layers (e.g., the dielectric layer DL) of the interconnect structure 104 may extend across the surface of the semiconductor substrate 102, while the conductive features of the interconnect structure 104 are formed in each of device regions R1 and not in the scribe line region R2 to keep the scribe line region R2 as a metal-free region to facilitate the subsequent blade sawing processes. Other structures (e.g., the bonding structure 105 and the redistribution structure 108) in structure 100 including dielectric layer(s) and conductive features may also be designed in the same manner, and will not be repeated below.

The bonding structure 105 is disposed on the first surface 102A of the semiconductor substrate 102, and the interconnect structure 104 is disposed between the bonding structure 105 and the semiconductor substrate 102. The bonding structure 105 may include a bonding dielectric layer 106 and a plurality of bonding conductors 107 embedded in the bonding dielectric layer 106. The bonding dielectric layer 106 may include a plurality of contact openings, and the bonding conductors 107 are exposed by the contact openings of the bonding dielectric layer 106. The bonding dielectric layer 106 may be a polymer such as PBO, polyimide, a BCB-based polymer, or the like; a nitride such as silicon nitride or the like; an oxide such as silicon oxide, a tetraethyl orthosilicate (TEOS) based oxide, phosphosilicate glass (PSG), borosilicate glass (BSG), boron-doped phosphosilicate glass (BPSG), or the like; or a combination thereof. The bonding dielectric layer 106 may be formed by spin coating, lamination, deposition (e.g., CVD such as low-pressure CVD (LPCVD), plasma enhanced CVD (PECVD), or high-density plasma CVD (HDPCVD)), or the like. The bonding conductors 107 may be conductive vias (e.g., copper vias), conductive pads (e.g., copper pads) or combinations thereof. The bonding conductors 107 may be formed of a metal such as aluminum, copper, alloys thereof or other suitable metallic material. The bonding conductors 107 may be formed by deposition, plating, damascene (such as a single damascene, a dual damascene, or the like) or other suitable processes. In some embodiments, top surfaces of the bonding conductors 107 are substantially level with a top surface of the bonding dielectric layer 106.

The plurality of integrated circuit dies 111 are bonded to the bonding structure 105. The plurality of integrated circuit dies 111 may include a logic die (e.g., a central processing unit (CPU), a graphics processing unit (GPU), a system-on-a-chip (SoC), an application processor (AP), a microcontroller, or the like), a memory die (e.g., a dynamic random access memory (DRAM) die, a static random access memory (SRAM) die, a high bandwidth memory (HBM) die, or the like), a power management die (e.g., a power management integrated circuit (PMIC) die), a radio frequency (RF) die, a sensor die, a micro-electro-mechanical-system (MEMS) die, a signal processing die (e.g., a digital signal processing (DSP) die or the like), a front-end die (e.g., an analog front-end (AFE) die), an input-output(I/O) die, the like, or a combination thereof.

As shown in FIG. 1, each of the plurality of integrated circuit dies 111 may include a substrate 112, an interconnect structure 113 and a bonding structure 114, but not limited thereto. One or more layers or components may be included in each of the plurality of integrated circuit dies 111 according to different needs.

The substrate 112 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the substrate 112 is made of semiconductor materials, such as semiconductor materials of the groups III-V of the periodic table. In some embodiments, the substrate 112 includes elementary semiconductor materials such as silicon or germanium; compound semiconductor materials such as silicon carbide, gallium arsenide, indium arsenide, or indium phosphide; alloy semiconductor materials such as SiGe, GaAsP, AlInAs, AlGaAs, GaInAs, GaInP, or GaInAsP; or combinations thereof. Other substrates, such as multi-layered or gradient substrates, may also be used. In some embodiments, although not shown, the substrate further includes active or passive devices, such as transistors, capacitors, resistors, or diodes formed therein.

The interconnect structure 113 is disposed between the substrate 112 and the bonding structure 114 and between the substrate 112 and the bonding structure 105. Although not shown, the bonding structure 105 may include one or more stacked dielectric layers and one or more layers of conductive features formed in the one or more stacked dielectric layers. The material and formation method of the dielectric layers and conductive features of the interconnect structure 113 may refer to those described with respect to the dielectric layers and conductive features of the interconnect structure 104, which will not be repeated here.

The bonding structure 114 is disposed between the interconnect structure 113 and the bonding structure 105, and the bonding structure 114 is bonded to the bonding structure 105. The bonding structure 114 may include a bonding dielectric layer 115 and a plurality of bonding conductors 116 embedded in the bonding dielectric layer 115. The material and formation method of the bonding dielectric layer 115 and the plurality of bonding conductors 116 of the bonding structure 114 may refer to those described with respect to the bonding dielectric layer 106 and the plurality of bonding conductors 107 of the bonding structure 105, which will not be repeated here.

In some embodiments, the bonding dielectric layer 115 is bonded to the bonding dielectric layer 106 through dielectric-to-dielectric bonding, without using any adhesive material (e.g., die attach film), and the plurality of bonding conductors 116 is bonded to the plurality of bonding conductors 107 through metal-to-metal bonding, without using any eutectic material (e.g., solder). The bonding between the bonding structure 114 and the bonding structure 105 may include a pre-bonding and an annealing. During the pre-bonding, a small pressing force is applied to press the structures against one another. The pre-bonding is performed at a low temperature, such as room temperature, such as a temperature in the range of about 15° C. to about 30° C., and after the pre-bonding, the bonding dielectric layer 115 and the bonding dielectric layer 106 are bonded to each other. The bonding strength is then improved in a subsequent annealing step, in which the bonding dielectric layer 115 and the bonding dielectric layer 106 are annealed at a high temperature, such as a temperature in the range of about 100° C. to about 400° C. After the annealing, bonds, such as fusions bonds, are formed bonding the bonding dielectric layer 115 and the bonding dielectric layer 106. For example, the bonds can be covalent bonds between the material of the bonding dielectric layer 115 and the material of the bonding dielectric layer 106. The plurality of bonding conductors 116 and the plurality of bonding conductors 107 are connected to each other with a one-to-one correspondence. The plurality of bonding conductors 116 and the plurality of bonding conductors 107 may be in physical contact after the pre-bonding, or may expand to be brought into physical contact during the annealing. Further, during the annealing, the material of the plurality of bonding conductors 116 and the plurality of bonding conductors 107 (e.g., copper) intermingles, so that metal-to-metal bonds are also formed.

The gap filling layer 117 is disposed on the bonding structure 105 and laterally surrounding the plurality of integrated circuit dies 111 to fill gap regions between the plurality of integrated circuit dies 111. The gap filling layer 117 may include an organic insulating material, an inorganic insulating material, a molding compound, epoxy, a molding underfill, a resin (such as an epoxy resin), glue, or the like. The gap filling layer 117 may be formed by CVD, over-molding, compression molding, immersion molding, transfer molding, or the like, and the plurality of integrated circuit dies 111 may be buried or covered by the gap filling layer 117. In some embodiments, the gap filling layer 117 may be applied in liquid or semi-liquid form and then subsequently cured. Optionally, a planarization process may be performed on the gap filling layer 117 to expose the plurality of integrated circuit dies 111. Surfaces of the plurality of integrated circuit dies 111 and the gap filling layer 117 may be substantially coplanar (e.g., level) after the planarization process, within process variations. The planarization process may be, for example, a chemical-mechanical polish (CMP), a grinding process, or the like. In some embodiments, the planarization may be omitted, for example, if the plurality of integrated circuit dies 111 are already exposed by the gap filling layer 117.

The bonding film 118 is disposed on the gap filling layer 117 and the plurality of integrated circuit dies 111 exposed by the gap filling layer 117. The bonding film 118 may be dispensed as a liquid and cured, may be a laminate film laminated onto the gap filling layer 117 and the plurality of integrated circuit dies 111 exposed by the gap filling layer 117, or may be the like. The bonding film 118 may be any suitable adhesive, polymer, polyimide, epoxy, DAF, TIM, or the like.

The bonding film 119 is disposed on the semiconductor substrate 101. The bonding film 119 may be dispensed as a liquid and cured, may be a laminate film laminated onto the semiconductor substrate 101, or may be the like. The bonding film 119 may be any suitable adhesive, polymer, polyimide, epoxy, DAF, TIM, or the like. And then, the bonding film 118 is bonded to the bonding film 119.

After sequentially forming the interconnect structure 104, the bonding structure 105, the plurality of integrated circuit dies 111, the gap filling layer 117 and the bonding film 118 on the first surface 102A of the semiconductor substrate 102 and bonding the semiconductor substrate 101 to the bonding film 118 through the bonding film 119, the resulting structure can be flipped over to perform the thinning process as described above on the second surface 102B of the semiconductor substrate 102 to expose the plurality of conductive vias 103. After the plurality of conductive vias 103 are exposed by the second surface 102B of the semiconductor substrate 102, the redistribution structure 108, the plurality of die connectors 109 and the plurality of conductive connectors 110 can be sequentially formed on the second surface 102B of the semiconductor substrate 102.

The redistribution structure 108 is formed on the second surface 102B of the semiconductor substrate 102 and electrically connected to the plurality of conductive vias 103. Although not shown, the redistribution structure 108 may include dielectric material layers and conductive features embedded in or formed on the dielectric material layers. The conductive features may also be referred to as redistribution layers or redistribution lines.

As an example of forming the redistribution structure 108, a first dielectric layer (not shown) within the dielectric material layers is deposited on the second surface 102B of the semiconductor substrate 102. In some embodiments, the first dielectric layer is formed of a photo-sensitive material such as PBO, polyimide, BCB, or the like, which may be patterned using a lithography mask. The first dielectric layer may be formed by spin coating, lamination, CVD, the like, or a combination thereof. The first dielectric layer is then patterned. The patterning forms openings exposing the plurality of conductive vias 103. The patterning may be by an acceptable process, such as by exposing and developing the first dielectric layer to light when the first dielectric layer is a photo-sensitive material or by etching using, for example, an anisotropic etch.

A first layer of conductive features (not shown) is then formed. The first layer of conductive features includes portions on and extending along the major surface of the first dielectric layer. The first layer of conductive features further includes portions extending through the first dielectric layer to physically and electrically couple the plurality of conductive vias 103. As an example to form the first layer of conductive features, a seed layer is formed over the first dielectric layer and in the openings of the first dielectric layer. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the first layer of conductive features. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, like copper, titanium, tungsten, aluminum, or the like. The combination of the conductive material and underlying portions of the seed layer form the first layer of conductive features. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

A second dielectric layer (not shown) within the dielectric material layers is deposited on the first dielectric layer and the first layer of conductive features. The second dielectric layer may be formed in a manner similar to the first dielectric layer, and may be formed of a similar material as the first dielectric layer.

A second layer of conductive features (not shown) is then formed. The second layer of conductive features includes portions on and extending along the major surface of the second dielectric layer. The second layer of conductive features further includes portions extending through the second dielectric layer to physically and electrically couple the first layer of conductive features. The second layer of conductive features may be formed in a similar manner and of a similar material as the first layer of conductive features. In some embodiments, the second layer of conductive features has a different size and/or pitch than the first layer of conductive features.

The redistribution structure 108 is described as an example having two layers of conductive features. More or fewer dielectric material layers and conductive features may be formed in the redistribution structure 108. If fewer dielectric material layers and conductive features are to be formed, steps and process discussed above may be omitted. If more dielectric material layers and conductive features are to be formed, steps and processes discussed above may be repeated.

The plurality of die connectors 109 are disposed on and electrically connected to the redistribution structure 108. The plurality of die connectors 109 may be a plurality of conductive pillars, a plurality of conductive pads, or the like, to which external connections are made. The plurality of die connectors 109 can be formed of a metal, such as copper, aluminum, or the like, and can be formed by, for example, plating, or the like.

The plurality of conductive connectors 110 are disposed on and electrically connected to the plurality of die connectors 109. The plurality of conductive connectors 110 may be ball grid array (BGA) connectors, a plurality of solder balls, a plurality of metal pillars, a plurality of controlled collapse chip connection (C4) bumps, a plurality of micro bumps, a plurality of electroless nickel-electroless palladium-immersion gold technique (ENEPIG)-formed bumps, or the like. The plurality of conductive connectors 110 may include a conductive material such as solder, copper, aluminum, gold, nickel, silver, palladium, tin, the like, or a combination thereof. In some embodiments, the plurality of conductive connectors 110 are formed by initially forming a layer of solder through evaporation, electroplating, printing, solder transfer, ball placement, or the like. Once a layer of solder has been formed on the structure, a reflow may be performed in order to shape the material into the desired bump shapes. In other embodiments, the plurality of conductive connectors 110 includes a plurality of metal pillars (such as a plurality of copper pillars) formed by sputtering, printing, electroplating, electroless plating, CVD, or the like. In embodiments in which the plurality of conductive connectors 110 includes a plurality of metal pillars, the plurality of metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In FIG. 1, a singulation process is performed to separate the structure 100 into a plurality of semiconductor structures (e.g., a semiconductor structure 200 shown in FIG. 2). The singulation process may be performed by two blade sawing processes along the scribe line region R2 (e.g., a metal-free region) between the device regions R1. The two blade sawing processes separate the individual semiconductor structures.

Specifically, in FIG. 1, the upper thin dashed line frame represents the region cut by a saw blade (not shown) in the first blade sawing process BS1, and the lower thin dashed line frame represents the region cut by a saw blade (not shown) in the second blade sawing process BS2. Based on considerations of processing results (e.g., high processing accuracy, less damage to sidewall surfaces caused by the saw blade, fewer defects), saw blade life, saw blade durability, or the like, the saw blades used in the two blade sawing processes may be saw blades with high wear bonding, small grit size and/or low diamond concentration. For example, the saw blades may be nickel saw blades, resin saw blades or the like.

In the first blade sawing process BS1, as shown in FIG. 1, the saw blade starts cutting from the top of structure 100, sequentially cuts through the redistribution structure 108, the semiconductor substrate 102, the dielectric layer DL of the interconnect structure 104, the bonding dielectric layer 106 of the bonding structure 105 and stops at the inside of the gap filling layer 117 without cutting through the gap filling layer 117. For example, the saw blade stops at a distance of about 10% to 20% of a thickness T117 of the gap filling layer 117 from the top surface of the gap filling layer 117. In the second blade sawing process BS2, as shown in FIG. 1, the saw blade starts cutting from the position where the saw blade in the first blade sawing process BS1 stops and cuts through the gap filling layer 117, the bonding film 118, the bonding film 119 and the semiconductor substrate 101 in sequence.

During the first blade sawing process BS1, the semiconductor substrate 102 disposed on the dielectric layer DL provides a hard force-applying surface, which is beneficial for the saw blade to cut through the dielectric layer DL. In some embodiments, the young's modulus of the semiconductor substrate 102 ranges from 165 GPa to 202 GPa to improve the ability or probability of cutting off the dielectric layer DL.

In addition, during the first blade sawing process BS1, the semiconductor substrate 102 disposed on the dielectric layer DL can resist the peeling force generated by the rotating sawblade, which helps to reduce the peeling of the dielectric layer DL. In some embodiments, a thickness T102 of the semiconductor substrate 102 ranges from 5 μm to 50 μm (i.e., 5 μm≤T102≤50 μm) to reduce the chance of the peeling of the dielectric layer DL.

Using blade sawing rather than laser grooving to cut the dielectric layer DL disposed under the semiconductor substrate 102 can improve the aforementioned recast and delamination issues generated by laser grooving and/or shorten the processing time. Moreover, since the first blade sawing process BS1 cuts through the dielectric layer DL and stops at the upper portion of the gap filling layer 117, rather than stopping immediately when cutting through the dielectric layer DL, the load of the saw blade can be reduced, the sticking of the dielectric layer DL to the saw blade can be reduced, and/or the difficulty of the second blade sawing process BS2 can be reduced.

In some embodiments, as shown in FIG. 1, a cutting width W2 of the second blade sawing process BS2 can be narrower than a cutting width W1 of the first blade sawing process BS1 to provide a buffer for variations (e.g., variations in saw blade width, and/or variations in saw blade shift during the singulation process.) As a result, in the semiconductor structure 200 formed by the singulation process, as shown in FIG. 2 and FIG. 3, a sidewall surface SDL of the dielectric layer DL is aligned with a sidewall surface S102 of the semiconductor substrate 102 disposed on the dielectric layer DL, while a sidewall surface S101 of the semiconductor substrate 101 disposed below the dielectric layer DL may protrude outward from the sidewall surface SDL of the dielectric layer DL (alternatively speaking, the sidewall surface SDL of the dielectric layer DL is retracted from the sidewall surface S101 of the semiconductor substrate 101 by a distance). In addition, since blade sawing processes can provide a vertical or nearly vertical sidewall surface for the cut object (e.g., the structure 100 shown in FIG. 1), a maximum lateral distance (e.g., a maximum distance along a direction D1) between two opposite ends of each of the sidewall surfaces (generated by the two blade sawing processes) of the semiconductor substrates (e.g., 101, 102) and dielectric layer (e.g., DL) can be less than 5 μm. Moreover, since the blade saw in the first blade sawing process BS1 stops inside the structure 100 on which the first blade sawing process BS1 is performed, an arc-shaped structure generated by the first blade sawing process BS1 may be formed inside the resulting semiconductor structure 200.

As shown in FIG. 2 and FIG. 3, a semiconductor structure 200 formed by the singulation process described above is provided. The semiconductor structure 200 includes, for example, a first semiconductor substrate (e.g., the semiconductor substrate 101), a second semiconductor substrate (e.g., the semiconductor substrate 102) disposed on the first semiconductor substrate and a dielectric layer DL disposed between the first semiconductor substrate and the second semiconductor substrate, wherein in a cross-sectional view, as shown in FIG. 2, a sidewall surface SDL of the dielectric layer DL is aligned with a sidewall surface S102 of the second semiconductor substrate (e.g., the semiconductor substrate 102), and a sidewall surface S101 of the first semiconductor substrate (e.g., the semiconductor substrate 101) protrudes outward from the sidewall surface SDL of the dielectric layer DL.

Optionally, the semiconductor structure 200 may further include the aforementioned components, layers and/or structures, such as the plurality of conductive vias 103, the one or more layers of conductive features of the interconnect structure 104, the bonding structure 105, the redistribution structure 108, the plurality of die connectors 109, the plurality of conductive connectors 110, the plurality of integrated circuit dies 111, the gap filling layer 117, the bonding film 118 and the bonding film 119, but not limited thereto. One or more components, layers and/or structures may be included additionally in the semiconductor structure 200, or one or more aforementioned components, layers and/or structures may not be included in the semiconductor structure 200 according to different needs.

In some embodiments, as described above, the dielectric layer DL has a dielectric constant less than 3. In some embodiments, as described above, the young's modulus of the second semiconductor substrate (e.g., the semiconductor substrate 102) ranges from 165 GPa to 202 GPa to improve the ability or probability of cutting off the dielectric layer DL. In some embodiments, as described above, the thickness T102 of the second semiconductor substrate (e.g., the semiconductor substrate 102) ranges from 5 μm to 50 μm (i.e., 5 μm≤T102≤50 μm) to reduce the chance of the peeling of the dielectric layer DL.

In some embodiments, as described above, the semiconductor structure 200 further includes the gap filling layer 117 disposed between the first semiconductor substrate (e.g., the semiconductor substrate 101) and the dielectric layer DL. The gap filling layer 117 has a sidewall surface S117 located between the sidewall surface S101 of the first semiconductor substrate (e.g., the semiconductor substrate 101) and the sidewall surface SDL of the dielectric layer DL. As shown in FIG. 2 or FIG. 3, the sidewall surface S117 of the gap filling layer 117 may include a first portion P1, a second portion P2 and a third portion P3 connecting the first portion P1 and the second portion P2. The first portion P1 is closer to the sidewall surface S101 of the first semiconductor substrate (e.g., the semiconductor substrate 101) than the second portion P2. The first portion P1 is formed by the second blade sawing process, while the second portion P2 and the third portion P3 are formed by the first blade sawing process. As a result, in the cross-sectional view, as shown in FIG. 2, the first portion P1 is aligned with the sidewall surface S101 of the first semiconductor substrate (e.g., the semiconductor substrate 101), and the second portion P2 is aligned with the sidewall surface SDL of the dielectric layer DL and the sidewall surface S102 of the second semiconductor substrate (e.g., the semiconductor substrate 102).

In some embodiments, as described above and as shown in FIG. 3, a boundary B between the second portion P2 and the third portion P3 of the sidewall surface S117 of the gap filling layer 117 includes an arc surface, which is generated by the saw blade in the first blade sawing process. In some embodiments, as described above, in the cross-sectional view, as shown in FIG. 2, the second portion P2 and the third portion P3 accounts for 10% to 20% of the thickness T117 of the gap filling layer 117. For example, a depth TT of a groove formed in the gap filling layer 117 by the first saw cutting process accounts for 10% to 20% of the thickness T117 of the gap filling layer 117.

From another perspective, the semiconductor structure 200 includes a first sidewall surface SW1, a second sidewall surface SW2 and a connection surface SC connecting the first sidewall surface SW1 and the second sidewall surface SW2. For example, as shown in FIG. 2, the first sidewall surface SW1 may include the sidewall surface S101 of the first semiconductor substrate (e.g., the semiconductor substrate 101), a sidewall surface S119 of the bonding film 119, a sidewall surface S118 of the bonding film 118 and the first portion P1 of the sidewall surface S117 of the gap filling layer 117; the second sidewall surface SW2 may include the second portion P2 of the sidewall surface S117 of the gap filling layer 117, a sidewall surface S106 of the bonding dielectric layer 106 of the bonding structure 105, the sidewall surface SDL of the dielectric layer DL, the sidewall surface S102 of the second semiconductor substrate (e.g., the semiconductor substrate 102) and a sidewall surface S108 of the redistribution structure 108; and the connection surface SC may include the third portion P3 of the sidewall surface S117 of the gap filling layer 117.

In the cross-sectional view, as shown in FIG. 2, the first sidewall surface SW1, the connection surface SC and the second sidewall surface SW2 are arranged along a thickness direction D2 of the semiconductor structure 200 on a side of the semiconductor structure 200. Specifically, the first sidewall surface SW1 is formed by the aforementioned first blade sawing process, while the connection surface SC and the second sidewall surface SW2 are formed by the aforementioned second blade sawing process. Therefore, the first sidewall surface SW1, the connection surface SC and the second sidewall surface SW2 are located on the same side of the semiconductor structure 200 and may be sequentially arranged along the thickness direction D2.

In the cross-sectional view, as shown in FIG. 2, a maximum lateral distance (e.g., a maximum distance along the direction D1) between two opposite ends (e.g., an end X1 and an end X2) of the first sidewall surface SW1 is less than 5 μm, and a maximum lateral distance between two opposite ends (e.g., an end X3 and an end X4) of the second sidewall surface SW2 is less than 5 μm. Specifically, as described above, since blade sawing processes can provide a vertical or nearly vertical sidewall surface for the cut object (e.g., the structure 100 shown in FIG. 1), a maximum lateral distance between two opposite ends of each of the sidewall surfaces (generated by the two blade sawing processes) can be less than 5 μm.

In some embodiments, as described above and as shown in FIG. 2 or FIG. 3, a boundary B between the second sidewall surface SW2 and the connection surface SC includes an arc surface, which is generated by the saw blade in the first blade sawing process.

Referring to FIG. 4, a structure 300 to be separated into a plurality of semiconductor structures (e.g., a semiconductor structure 400 shown in FIG. 5) through a singulation process is provided. The structure 300 includes, for example, a semiconductor substrate 301, a semiconductor substrate 302, a plurality of conductive vias 303, an interconnect structure 304, a first bonding structure 305, a release layer 308, an insulation layer 309, a plurality of pads 310, a second bonding structure 311, a bonding film 314 and a bonding film 315, but not limited thereto. One or more layers or components may be included in the structure 300 according to different needs.

The semiconductor substrate 301 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the semiconductor substrate 301 is made of semiconductor materials, such as semiconductor materials of the groups III-V of the periodic table. In some embodiments, the semiconductor substrate 301 includes elementary semiconductor materials such as silicon or germanium; compound semiconductor materials such as silicon carbide, gallium arsenide, indium arsenide, or indium phosphide; alloy semiconductor materials such as SiGe, GaAsP, AlInAs, AlGaAs, GaInAs, GaInP, or GaInAsP; or combinations thereof. Other substrates, such as multi-layered or gradient substrates, may also be used.

The semiconductor substrate 302 is disposed on the semiconductor substrate 301. The semiconductor substrate 302 may be or includes a monocrystalline semiconductor substrate such as a silicon substrate, a silicon-on-insulator (SOI) substrate, silicon-germanium on insulator (SGOI) or a germanium-on-insulator (GOI) substrate. In some embodiments, the semiconductor substrate 302 is made of semiconductor materials, such as semiconductor materials of the groups III-V of the periodic table. In some embodiments, the semiconductor substrate 102 includes elementary semiconductor materials such as silicon or germanium; compound semiconductor materials such as silicon carbide, gallium arsenide, indium arsenide, or indium phosphide; alloy semiconductor materials such as SiGe, GaAsP, AlInAs, AlGaAs, GaInAs, GaInP, or GaInAsP; or combinations thereof. Other substrates, such as multi-layered or gradient substrates, may also be used. In some embodiments, although not shown, the semiconductor substrate further includes active or passive devices, such as transistors, capacitors, resistors, or diodes formed therein. FIG. 4 schematically illustrates a local silicon interconnect (LSI) die 316 formed in the semiconductor substrate 302, but the disclosure is not limited thereto. The composition and/or material of the semiconductor substrate 301 and the semiconductor substrate 302 may be different or the same.

The plurality of conductive vias 303 extend through the semiconductor substrate 302 (the plurality of conductive vias 303 is exposed by both of a first surface 302A and a second surface 302B of the semiconductor substrate 302) and can be referred to as through-silicon vias or through-substrate vias (TSVs). The material and formation method of the plurality of conductive vias 303 may refer to those described with respect to the plurality of conductive vias 103, which will not be repeated here.

The interconnect structure 304 is disposed on the first surface 302A of the semiconductor substrate 302. The interconnect structure 304 may interconnect elements on the same side or opposite sides of the semiconductor substrate 302. The interconnect structure 304 may include one or more stacked dielectric layers (only one dielectric layer DL is shown) and one or more layers of conductive features (not shown) formed in the one or more stacked dielectric layers. Each of the stacked dielectric layers may include a dielectric material having a dielectric constant less than 3, such as a low-k (low dielectric constant) material, an extreme low dielectric constant (ELK) material, or the like. The material and formation method of the one or more stacked dielectric layers and one or more layers of conductive features of the interconnect structure 304 may refer to those described with respect to the one or more stacked dielectric layers and one or more layers of conductive features of the interconnect structure 104, which will not be repeated here.

Although the interconnect structure 304 is illustrated in FIG. 4 as extending across a surface of the semiconductor substrate 302, in some embodiments, individual interconnect structures 304 may be formed in each of device regions R1 and the individual interconnect structures 304 may be separated from one another by a scribe line region R2. The interconnect structure 304 may be separated using a suitable etching process, such as an isotropic etching process (e.g., a wet etching process), an anisotropic etching process (e.g., a dry etching process), multiple processes or combinations thereof, or the like.

Alternatively, dielectric layers (e.g., the dielectric layer DL) of the interconnect structure 304 may extend across the surface of the semiconductor substrate 302, while the conductive features of the interconnect structure 304 are formed in each of device regions R1 and not in the scribe line region R2 to keep the scribe line region R2 as a metal-free region to facilitate the subsequent blade sawing processes. Other structures (e.g., the first bonding structure 305 and the second bonding structure 311) in structure 300 including dielectric layer(s) and conductive features may also be designed in the same manner, and will not be repeated below.

The first bonding structure 305 is disposed on the first surface 302A of the semiconductor substrate 302, and the interconnect structure 304 is disposed between the first bonding structure 305 and the semiconductor substrate 302. The first bonding structure 105 may include a first bonding dielectric layer 306 and a plurality of first bonding conductors 307 embedded in the first bonding dielectric layer 306. The material and formation method of the first bonding dielectric layer 306 and the plurality of first bonding conductors 307 of the first bonding structure 305 may refer to those described with respect to the bonding dielectric layer 106 and the plurality of bonding conductors 107 of the bonding structure 105, which will not be repeated here. At this step, top surfaces of the first bonding conductors 307 are substantially level with a top surface of the first bonding dielectric layer 306, and bottom surfaces of the first bonding conductors 307 are located between the top surface of the first bonding dielectric layer 306 and a bottom surface of the first bonding dielectric layer 306.

The release layer 308 is disposed between the semiconductor substrate 301 and the first bonding structure 305. The release layer 308 may be formed of a polymer-based material, which may be removed along with the semiconductor substrate 301 from the overlying structures. In some embodiments, the release layer 308 is an epoxy-based thermal-release material, which loses its adhesive property when heated, such as a light-to-heat-conversion (LTHC) release coating. In other embodiments, the release layer 308 may be an ultra-violet (UV) glue, which loses its adhesive property when exposed to UV lights. The release layer 308 may be dispensed as a liquid and cured, may be a laminate film laminated onto the semiconductor substrate 301, or may be the like.

The insulation layer 309 is disposed on the second surfaces 302B of the semiconductor substrate 302 and has a plurality of openings exposing the plurality of conductive vias 303. The insulation layer 309 may be formed from an oxide, a nitride, an oxynitride, a combination thereof, and/or the like. The plurality of pads 310 are disposed in the plurality of openings of the insulation layer 309, and the plurality of pads 310 may be formed from a conductive material, such as copper, copper alloy, silver, gold, tungsten, aluminum, ruthenium, cobalt, molybdenum, combinations thereof, or the like.

The second bonding structure 311 is disposed on the insulation layer 309 and the plurality of pads 310. The second bonding structure 311 may include a second bonding dielectric layer 312 and a plurality of second bonding conductors 313 embedded in the second bonding dielectric layer 312. The plurality of second bonding conductors 313 may be conductive vias (e.g., copper vias), conductive pads (e.g., copper pads) or combinations thereof. The plurality of second bonding conductors 313 may be formed of a metal such as aluminum, copper, alloys thereof or other suitable metallic material. The second bonding dielectric layer 312 may be a molding compound, a molding underfill, a resin (such as an epoxy resin), glue, or the like. In some embodiments, the second bonding dielectric layer 312 is formed by an over-molding process, such that not only sidewall surfaces of the plurality of second bonding conductors 313 but also surfaces of the plurality of second bonding conductors 313 away from the semiconductor substrate 302 are encapsulated/covered by the second bonding dielectric layer 312. In some embodiments, the second bonding dielectric layer 312 is formed by at least one of a compression molding process, an immersion molding process and a transfer molding process. In some embodiments, the second bonding dielectric layer 312 may be applied in liquid or semi-liquid form and then subsequently cured. Optionally, a planarization process may be performed on the second bonding dielectric layer 312 to expose the plurality of second bonding conductors 313. Surfaces of the plurality of second bonding conductors 313 and the second bonding dielectric layer 312 may be substantially coplanar (e.g., level) after the planarization process, within process variations. The planarization process may be, for example, a chemical-mechanical polish (CMP), a grinding process, or the like. In some embodiments, the planarization may be omitted, for example, if the plurality of second bonding conductors 313 are already exposed by the second bonding dielectric layer 312.

The bonding film 314 and the bonding film 315 are sequentially formed on the second bonding structure 311. For example, the bonding film 314 is formed of polyimide, and the bonding film 315 is a die attach film (DAF).

In FIG. 4, a singulation process is performed to separate the structure 300 into a plurality of semiconductor structures (e.g., a semiconductor structure 400 shown in FIG. 5). The singulation process may be performed by one laser grooving process and two blade sawing processes along the scribe line region R2 (e.g., a metal-free region) between the device regions R1. The one laser grooving process and two blade sawing processes separate the individual semiconductor structures.

Specifically, in FIG. 4, the thick dashed line frame represents the region cut by a laser beam (not shown) in the laser grooving process LG, the upper thin dashed line frame represents the region cut by a saw blade (not shown) in the first blade sawing process BS1, and the lower thin dashed line frame represents the region cut by a saw blade (not shown) in the second blade sawing process BS2.

In the laser grooving process LG, as shown in FIG. 4, the laser beam sequentially cuts through the bonding film 315, the bonding film 314, the second bonding dielectric layer 312 of the second bonding structure 311 and the insulation layer 309 and stops on top of the semiconductor substrate 302 without cutting the semiconductor substrate 302 to avoid recasting at the sidewall surface of the semiconductor substrate 302. In the first blade sawing process BS1, as shown in FIG. 4, the saw blade starts cutting from the second surface 302B of the semiconductor substrate 302, sequentially cuts through the semiconductor substrate 302, the dielectric layer DL of the interconnect structure 304 and stops at the inside of the first bonding dielectric layer 306 of the first bonding structure 305 without cutting through first bonding dielectric layer 306. For example, the saw blade stops at a distance of about 10% to 20% of a thickness T306 of the first bonding dielectric layer 306 from the top surface of the first bonding dielectric layer 306. In the second blade sawing process BS2, as shown in FIG. 4, the saw blade starts cutting from the position where the saw blade in the first blade sawing process BS1 stops and cuts through the first bonding dielectric layer 306 of the first bonding structure 305, the release layer 308 and the semiconductor substrate 301 in sequence.

During the first blade sawing process BS1, the semiconductor substrate 302 disposed on the dielectric layer DL provides a hard force-applying surface, which is beneficial for the saw blade to cut through the dielectric layer DL. In some embodiments, the young's modulus of the semiconductor substrate 302 ranges from 165 GPa to 202 GPa to improve the ability or probability of cutting off the dielectric layer DL.

In addition, during the first blade sawing process BS1, the semiconductor substrate 302 disposed on the dielectric layer DL can resist the peeling force generated by the rotating sawblade, which helps to reduce the peeling of the dielectric layer DL. In some embodiments, a thickness T302 of the semiconductor substrate 302 ranges from 5 μm to 50 μm (i.e., 5 μm≤T302≤50 μm) to reduce the chance of the peeling of the dielectric layer DL.

Using blade sawing rather than laser grooving to cut the dielectric layer DL disposed under the semiconductor substrate 302 can improve the aforementioned recast and delamination issues generated by laser grooving and/or shorten the processing time. Moreover, since the first blade sawing process BS1 cuts through the dielectric layer DL and stops at the upper portion of the first bonding dielectric layer 306, rather than stopping immediately when cutting through the dielectric layer DL, the load of the saw blade can be reduced, the sticking of the dielectric layer DL to the saw blade can be reduced, and/or the difficulty of the second blade sawing process BS2 can be reduced.

In some embodiments, as shown in FIG. 4, the cutting width W2 of the second blade sawing process BS2 can be narrower than the cutting width W1 of the first blade sawing process BS1 and a minimum cutting width WLG of the laser grooving process LG can be narrower than the cutting width W1 of the first blade sawing process BS1 to provide a buffer for variations.

As shown in FIG. 5 and FIG. 6, after the singulation process illustrated in FIG. 4, a de-bonding process is performed to detach (or “de-bond”) the semiconductor substrate 301 from the structure and to detach the bonding film 314 and the bonding film 315 from the second bonding structure 311. As a result, a semiconductor structure 400 is formed. The semiconductor structure 400 includes, for example, the first bonding structure 305, the interconnect structure 304, the semiconductor substrate 302, the plurality of conductive vias 303, the insulation layer 309, the plurality of pads 310 and the second bonding structure 311, but not limited thereto. One or more components, layers and/or structures may be included additionally in the semiconductor structure 400, or one or more aforementioned components, layers and/or structures may not be included in the semiconductor structure 400 according to different needs.

In some embodiments, as described above, the dielectric layer DL has a dielectric constant less than 3. In some embodiments, as described above, the young's modulus of the semiconductor substrate 302 ranges from 165 GPa to 202 GPa to improve the ability or probability of cutting off the dielectric layer DL. In some embodiments, as described above, the thickness T302 of the semiconductor substrate 302 ranges from 5 μm to 50 μm (i.e., 5 μm≤T302≤50 μm) to reduce the chance of the peeling of the dielectric layer DL.

In some embodiments, a sidewall surface S307 of the first bonding dielectric layer 307 includes a first portion P1, a second portion P2 and a third portion P3 connecting the first portion P1 and the second portion P2. The first portion P1 is formed by the second blade sawing process, while the second portion P2 and the third portion P3 are formed by the first blade sawing process. As a result, in the cross-sectional view, as shown in FIG. 5, the second portion P2 is aligned with the sidewall surface SDL of the dielectric layer DL and the sidewall surface S302 of the semiconductor substrate 302, and the first portion P1 protrudes outward from the sidewall surface SDL of the dielectric layer DL.

In some embodiments, as described above and as shown in FIG. 5, a boundary B between the second portion P2 and the third portion P3 of the sidewall surface S307 of the first bonding dielectric layer 307 includes an arc surface, which is generated by the saw blade in the first blade sawing process. In some embodiments, as described above, in the cross-sectional view, as shown in FIG. 5, the second portion P2 and the third portion P3 accounts for 10% to 20% of the thickness T307 of the first bonding dielectric layer 307. For example, a depth TT of a groove formed in the first bonding dielectric layer 307 by the first saw cutting process accounts for 10% to 20% of the thickness T307 of the first bonding dielectric layer 307.

From another perspective, the semiconductor structure 400 includes a first sidewall surface SW1, a second sidewall surface SW2, a third sidewall surface SW3, a first connection surface SC1 connecting the first sidewall surface SW1 and the second sidewall surface SW2 and a second connection surface SC2 connecting the second sidewall surface SW2 and the third sidewall surface SW3. For example, as shown in FIG. 5, the first sidewall surface SW1 may include the first portion P1 of the sidewall surface S307 of the first bonding dielectric layer 307; the second sidewall surface SW2 may include the second portion P2 of the sidewall surface S307 of the first bonding dielectric layer 307, the sidewall surface SDL of the dielectric layer DL and the sidewall surface S302 of the semiconductor substrate 302; the third sidewall surface SW3 may include a sidewall surface S309 of the insulation layer 309 and a sidewall surface S312 of the second bonding dielectric layer 312 of the second bonding structure 311; the first connection surface SC1 may include the third portion P3 of the sidewall surface S307 of the first bonding dielectric layer 307; and the second connection surface SC2 may include a portion of the second surface 302B of the semiconductor substrate 302 exposed by the insulation layer 309.

In the cross-sectional view, as shown in FIG. 5, the first sidewall surface SW1, the first connection surface SC1, the second sidewall surface SW2, the second connection surface SC2 and the third sidewall surface SW3 are arranged along a thickness direction D2 of the semiconductor structure 400 on a side of the semiconductor structure 400. Specifically, the first sidewall surface SW1 is formed by the aforementioned first blade sawing process, the first connection surface SC1 and the second sidewall surface SW2 are formed by the aforementioned second blade sawing process, while the second connection surface SC2 and the third sidewall surface SW3 are formed by the aforementioned laser grooving process. Therefore, the first sidewall surface SW1, the first connection surface SC1, the second sidewall surface SW2, the second connection surface SC2 and the third sidewall surface SW3 are located on the same side of the semiconductor structure 400 and may be sequentially arranged along the thickness direction D2.

In the cross-sectional view, as shown in FIG. 5, the first sidewall surface SW1 and the second sidewall surface SW2 are steeper than the third sidewall surface SW3. Specifically, laser beams have divergence angles (the beam diameter increases as the distance to the focal point increases), so the third sidewall surface SW3 produced by the laser grooving process is inclined rather than vertical. As a result, the first sidewall surface SW1 and the second sidewall surface SW2 produced by the two blade sawing processes are steeper than the third sidewall surface SW3 produced by the laser grooving process.

As shown in FIG. 5, a maximum lateral distance (e.g., a maximum distance along the direction D1) between two opposite ends (e.g., an end X5 and an end X6) of the first sidewall surface SW1 is less than 5 μm, a maximum lateral distance between two opposite ends (e.g., an end X7 and an end X8) of the second sidewall surface SW2 is less than 5 μm, and a maximum lateral distance LD between two opposite ends (e.g., an end X9 and an end X10) of the third sidewall surface is greater than 5 μm. Specifically, as described above, since blade sawing processes can provide a vertical or nearly vertical sidewall surface for the cut object (e.g., the structure 300 shown in FIG. 4), a maximum lateral distance between two opposite ends of each of the sidewall surfaces generated by the two blade sawing processes can be less than 5 μm.

In some embodiments, as described above and as shown in FIG. 5 or FIG. 6, a boundary B between the second sidewall surface SW2 and the first connection surface SC1 includes an arc surface, which is generated by the saw blade in the first blade sawing process.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a semiconductor structure includes a first semiconductor substrate, a second semiconductor substrate disposed on the first semiconductor substrate, and a dielectric layer disposed between the first semiconductor substrate and the second semiconductor substrate. In a cross-sectional view, a sidewall surface of the dielectric layer is aligned with a sidewall surface of the second semiconductor substrate, and a sidewall surface of the first semiconductor substrate protrudes outward from the sidewall surface of the dielectric layer. In some embodiments, the dielectric layer has a dielectric constant less than 3. In some embodiments, young's modulus of the second semiconductor substrate ranges from 165 GPa to 202 GPa. In some embodiments, a thickness of the second semiconductor substrate ranges from 5 μm to 50 μm. In some embodiments, the semiconductor structure further includes a gap filling layer disposed between the first semiconductor substrate and the dielectric layer. The gap filling layer has a sidewall surface located between the sidewall surface of the first semiconductor substrate and the sidewall surface of the dielectric layer. The sidewall surface of the gap filling layer includes a first portion, a second portion and a third portion connecting the first portion and the second portion. The first portion is closer to the sidewall surface of the first semiconductor substrate than the second portion. In the cross-sectional view, the first portion is aligned with the sidewall surface of the first semiconductor substrate, and the second portion is aligned with the sidewall surface of the dielectric layer and the sidewall surface of the second semiconductor substrate. In some embodiments, a boundary between the second portion and the third portion of the sidewall surface of the gap filling layer includes an arc surface. In some embodiments, in the cross-sectional view, the second portion and the third portion accounts for 10% to 20% of a thickness of the gap filling layer.

According to some embodiments, a semiconductor structure includes a first sidewall surface, a second sidewall surface and a connection surface connecting the first sidewall surface and the second sidewall surface. In a cross-sectional view, the first sidewall surface, the connection surface and the second sidewall surface are arranged along a thickness direction of the semiconductor structure on a side of the semiconductor structure, a maximum lateral distance between two opposite ends of the first sidewall surface is less than 5 μm, and a maximum lateral distance between two opposite ends of the second sidewall surface is less than 5 μm. In some embodiments, a boundary between the second sidewall surface and the connection surface includes an arc surface. In some embodiments, the semiconductor structure further includes a first semiconductor substrate, a second semiconductor substrate disposed on the first semiconductor substrate, a dielectric layer disposed between the first semiconductor substrate and the second semiconductor substrate, and a gap filling layer disposed between the first semiconductor substrate and the dielectric layer. A sidewall surface of the gap filling layer includes a first portion, a second portion and a third portion connecting the first portion and the second portion. The first sidewall surface includes the first portion of the sidewall surface of the gap filling layer and a sidewall surface of the first semiconductor substrate. The second sidewall surface includes the second portion of the sidewall surface of the gap filling layer, a sidewall surface of the dielectric layer and a sidewall surface of the second semiconductor substrate. The connection surface includes the third portion of the sidewall surface of the gap filling layer. In some embodiments, in the cross-sectional view, the second portion and the third portion accounts for 10% to 20% of a thickness of the gap filling layer. In some embodiments, the dielectric layer has a dielectric constant less than 3. In some embodiments, young's modulus of the second semiconductor substrate ranges from 165 GPa to 202 GPa. In some embodiments, a thickness of the second semiconductor substrate ranges from 5 μm to 50 μm.

According to some embodiments, a semiconductor structure includes a first sidewall surface, a second sidewall surface, a third sidewall surface, a first connection surface connecting the first sidewall surface and the second sidewall surface and a second connection surface connecting the second sidewall surface and the third sidewall surface. In a cross-sectional view, the first sidewall surface, the first connection surface, the second sidewall surface, the second connection surface and the third sidewall surface are arranged along a thickness direction of the semiconductor structure on a side of the semiconductor structure, the first sidewall surface and the second sidewall surface are steeper than the third sidewall surface, and a boundary between the first connection surface and the second sidewall surface includes an arc surface. In some embodiments, a maximum lateral distance between two opposite ends of the first sidewall surface is less than 5 μm, a maximum lateral distance between two opposite ends of the second sidewall surface is less than 5 μm, and a maximum lateral distance between two opposite ends of the third sidewall surface is greater than 5 μm. In some embodiments, the semiconductor structure further includes a semiconductor substrate having a first surface and a second surface opposite to the first surface; a first bonding structure disposed on the first surface and including a first bonding dielectric layer and a plurality of first bonding conductors embedded in the first bonding dielectric layer; a dielectric layer disposed between the first bonding structure and the semiconductor substrate; and a second bonding structure disposed on the second surface and including a second bonding dielectric layer and a plurality of second bonding conductors embedded in the second bonding dielectric layer. A sidewall surface of the first bonding dielectric layer includes a first portion, a second portion and a third portion connecting the first portion and the second portion. The first sidewall surface includes the first portion of the sidewall surface of the first bonding dielectric layer. The second sidewall surface includes the second portion of the sidewall surface of the first bonding dielectric layer, a sidewall surface of the dielectric layer and a sidewall surface of the semiconductor substrate. The third sidewall surface includes a sidewall surface of the second bonding dielectric layer. The first connection surface includes the third portion of the sidewall surface of the first bonding dielectric layer. The second connection surface includes a portion of the second surface. In some embodiments, in the cross-sectional view, the second portion and the third portion accounts for 10% to 20% of a thickness of the first bonding dielectric layer. In some embodiments, the dielectric layer has a dielectric constant less than 3. In some embodiments, the semiconductor structure further includes an interconnect structure disposed between the first bonding structure and the semiconductor substrate and including the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first semiconductor substrate;
a second semiconductor substrate disposed on the first semiconductor substrate; and
a dielectric layer disposed between the first semiconductor substrate and the second semiconductor substrate,
wherein in a cross-sectional view, a sidewall surface of the dielectric layer is aligned with a sidewall surface of the second semiconductor substrate, and a sidewall surface of the first semiconductor substrate protrudes outward from the sidewall surface of the dielectric layer.

2. The semiconductor structure as claimed in claim 1, wherein the dielectric layer has a dielectric constant less than 3.

3. The semiconductor structure as claimed in claim 1, wherein young's modulus of the second semiconductor substrate ranges from 165 GPa to 202 GPa.

4. The semiconductor structure as claimed in claim 1, wherein a thickness of the second semiconductor substrate ranges from 5 μm to 50 μm.

5. The semiconductor structure as claimed in claim 1, further comprising:
a gap filling layer disposed between the first semiconductor substrate and the dielectric layer, wherein:
the gap filling layer has a sidewall surface located between the sidewall surface of the first semiconductor substrate and the sidewall surface of the dielectric layer,
the sidewall surface of the gap filling layer comprises a first portion, a second portion and a third portion connecting the first portion and the second portion,
the first portion is closer to the sidewall surface of the first semiconductor substrate than the second portion, and
in the cross-sectional view, the first portion is aligned with the sidewall surface of the first semiconductor substrate, and the second portion is aligned with the sidewall surface of the dielectric layer and the sidewall surface of the second semiconductor substrate.

6. The semiconductor structure as claimed in claim 5, wherein a boundary between the second portion and the third portion of the sidewall surface of the gap filling layer comprises an arc surface.

7. The semiconductor structure as claimed in claim 5, wherein in the cross-sectional view, the second portion and the third portion accounts for 10% to 20% of a thickness of the gap filling layer.

8. A semiconductor structure, comprising:
a first sidewall surface, a second sidewall surface and a connection surface connecting the first sidewall surface and the second sidewall surface, wherein in a cross-sectional view:
the first sidewall surface, the connection surface and the second sidewall surface are arranged along a thickness direction of the semiconductor structure on a side of the semiconductor structure,
a maximum lateral distance between two opposite ends of the first sidewall surface is less than 5 μm, and
a maximum lateral distance between two opposite ends of the second sidewall surface is less than 5 μm.

9. The semiconductor structure as claimed in claim 8, wherein a boundary between the second sidewall surface and the connection surface comprises an arc surface.

10. The semiconductor structure as claimed in claim 8, further comprising:
a first semiconductor substrate;
a second semiconductor substrate disposed on the first semiconductor substrate;
a dielectric layer disposed between the first semiconductor substrate and the second semiconductor substrate; and
a gap filling layer disposed between the first semiconductor substrate and the dielectric layer, wherein:
a sidewall surface of the gap filling layer comprises a first portion, a second portion and a third portion connecting the first portion and the second portion,
the first sidewall surface comprises the first portion of the sidewall surface of the gap filling layer and a sidewall surface of the first semiconductor substrate,
the second sidewall surface comprises the second portion of the sidewall surface of the gap filling layer, a sidewall surface of the dielectric layer and a sidewall surface of the second semiconductor substrate, and
the connection surface comprises the third portion of the sidewall surface of the gap filling layer.

11. The semiconductor structure as claimed in claim 10, wherein in the cross-sectional view, the second portion and the third portion accounts for 10% to 20% of a thickness of the gap filling layer.

12. The semiconductor structure as claimed in claim 10, wherein the dielectric layer has a dielectric constant less than 3.

13. The semiconductor structure as claimed in claim 10, wherein young's modulus of the second semiconductor substrate ranges from 165 GPa to 202 GPa.

14. The semiconductor structure as claimed in claim 10, wherein a thickness of the second semiconductor substrate ranges from 5 μm to 50 μm.

15. A semiconductor structure, comprising:
a first sidewall surface, a second sidewall surface, a third sidewall surface, a first connection surface connecting the first sidewall surface and the second sidewall surface and a second connection surface connecting the second sidewall surface and the third sidewall surface, wherein in a cross-sectional view:
the first sidewall surface, the first connection surface, the second sidewall surface, the second connection surface and the third sidewall surface are arranged along a thickness direction of the semiconductor structure on a side of the semiconductor structure,
the first sidewall surface and the second sidewall surface are steeper than the third sidewall surface, and
a boundary between the first connection surface and the second sidewall surface comprises an arc surface.

16. The semiconductor structure as claimed in claim 15, wherein:
a maximum lateral distance between two opposite ends of the first sidewall surface is less than 5 μm,
a maximum lateral distance between two opposite ends of the second sidewall surface is less than 5 μm, and
a maximum lateral distance between two opposite ends of the third sidewall surface is greater than 5 μm.

17. The semiconductor structure as claimed in claim 15, further comprising:
a semiconductor substrate having a first surface and a second surface opposite to the first surface;
a first bonding structure disposed on the first surface and comprising a first bonding dielectric layer and a plurality of first bonding conductors embedded in the first bonding dielectric layer;
a dielectric layer disposed between the first bonding structure and the semiconductor substrate; and
a second bonding structure disposed on the second surface and comprising a second bonding dielectric layer and a plurality of second bonding conductors embedded in the second bonding dielectric layer, wherein:
a sidewall surface of the first bonding dielectric layer comprises a first portion, a second portion and a third portion connecting the first portion and the second portion,
the first sidewall surface comprises the first portion of the sidewall surface of the first bonding dielectric layer,
the second sidewall surface comprises the second portion of the sidewall surface of the first bonding dielectric layer, a sidewall surface of the dielectric layer and a sidewall surface of the semiconductor substrate,
the third sidewall surface comprises a sidewall surface of the second bonding dielectric layer,
the first connection surface comprises the third portion of the sidewall surface of the first bonding dielectric layer, and
the second connection surface comprises a portion of the second surface.

18. The semiconductor structure as claimed in claim 17, wherein in the cross-sectional view, the second portion and the third portion accounts for 10% to 20% of a thickness of the first bonding dielectric layer.

19. The semiconductor structure as claimed in claim 17, wherein the dielectric layer has a dielectric constant less than 3.

20. The semiconductor structure as claimed in claim 17, further comprising:
an interconnect structure disposed between the first bonding structure and the semiconductor substrate and comprising the dielectric layer.
